(19) United States
(12) Patent Application Publication
(10) Pub. No.: US 2025/0076751 A1
(43) Pub. Date: Mar. 6, 2025

(54) PELLICLE STRUCTURE

(71) Applicant: SK hynix Inc., Gyeonggi-do (KR)

(72) Inventor: Tae Joong HA, Gyeonggi-do (KR)

(21) Appl. No.: 18/762,650

(22) Filed: Jul. 3, 2024

(30) Foreign Application Priority Data
Aug. 28, 2023 (KR) 10-2023-0112915
Feb. 27, 2024 (KR) 10-2024-0027892

(51) Int. Cl. G03F 1/62

(52) U.S. Cl. CPC G03F 1/62

(57) ABSTRACT

A pellicle structure may include a membrane border and a pellicle membrane. The membrane border defines an open region. The membrane is in contact with the membrane border and extending over the open region. Thus, the membrane is capable of maintaining a thin film having a uniform thickness to prevent pattern errors.

### CROSS-REFERENCES TO RELATED APPLICATION

The present application claims priority under 35 U.S.C. § 119(a) to Korean patent application number 10-2023-0112915, filed on Aug. 28, 2023, and Korean patent application number 10-2024-0027892, filed on Feb. 27, 2024, which are incorporated herein by reference in their entirety.

### BACKGROUND

### 1. Technical Field

Various embodiments of the present disclosure relate generally to a semiconductor pattern manufacturing technology, and more particularly, to a pellicle structure configured to protect a photo mask.

### 2. Related Art

Generally, a pellicle structure protects a photo mask for forming a fine pattern by covering the surface of the photo mask facing the wafer. The pellicle structure may prevent surface contamination and photo mask deformation.

Typically, a pellicle structure includes a pellicle membrane. For manufacturing fine patterns, further improvements are being explored for the pellicle structures including for the pellicle membrane.

### SUMMARY

Various embodiments of the present disclosure provide a pellicle structure capable of preventing pattern errors. The pellicle structure may include a membrane capable of maintaining transmittance to an extreme ultraviolet (EUV) light source used as an exposure source for a photo lithography process.

The pellicle structure may include a membrane capable of maintaining a thin film having a uniform thickness to prevent pattern errors.

A pellicle structure of the embodiments of the present disclosure may include a membrane border defining an open region, and a pellicle membrane in contact with the membrane border and extending over the open region.

A pellicle structure of the embodiments of the present disclosure may include a membrane border and a pellicle membrane.

The membrane border may include an open region having a curvature portion adjacent to at least one edge of the open region. The membrane is attached to an edge of the membrane border.

In some embodiments of the present disclosure, a planar structure of the open region may be circular. Alternatively, the planar structure of the open region may be a polygon, and the curvature portion may be provided to at least one of the edges and corners of the open region.

A pellicle structure of the embodiments of the present disclosure may include a membrane, an outer border and an inner border. The outer border is disposed on edges of a lower surface of the membrane and the outer border includes a ring shape. The inner border is disposed inside the outer border and on the lower surface of the membrane. At least one of the edges of the membrane exposed by the outer border and the edge of the membrane exposed by the inner border may have a curvature.

A pellicle structure of the embodiments of the present disclosure may include a pellicle membrane and a pellicle frame. The pellicle frame includes an open region, and the pellicle frame is configured to expose the pellicle membrane through the open region. At least one of the edges of the pellicle membrane exposed through the open region may have a curvature.

A pellicle structure of the embodiments of the present disclosure may include a membrane defining an open region; and a pellicle membrane extending over the open region and contacting membrane border. The open region has a shape of wholly circular or part circular, or polygonal with at least one edge of the polygonal shape being wholly or partially extended with a curvature portion. the pellicle membrane is made of a material having a transmittance of about 80% or more with respect to extreme ultraviolet (EUV) light.

According to various embodiments of the present disclosure, the membrane border may include an open region in which a curvature portion is provided in at least a portion of the membrane border. A tension unbalance of the pellicle membrane is compensated for by the curvature portion, thereby preventing shape deformation such as wrinkles occurring at the edges or corners of the pellicle membrane. Thus, pattern errors due to wrinkles of the pellicle membrane may be prevented during a photo lithography process.

### BRIEF DESCRIPTION OF THE DRAWINGS

The above and another aspects, features and advantages of the subject matter of the present disclosure will be more clearly understood from the following detailed description taken in conjunction with the accompanying drawings, in which:

FIG. 1 is a simplified schematic block diagram of a photo lithography apparatus using a photo mask including a pellicle structure in accordance with an embodiment of the present disclosure;

FIG. 2 is a simplified schematic exploded perspective view of a mask assembly in accordance with an embodiments of the present disclosure;

FIG. 3A is a lower plan view of a pellicle structure in accordance with an embodiment of the present disclosure;

FIG. 3B is a cross-sectional view taken along a line a-a′ of FIG. 3A;

FIG. 4A is a lower plan view of a pellicle structure in accordance with embodiments of the present disclosure;

FIG. 4B is a cross-sectional view taken along a line b-b′ of FIG. 4A;

FIGS. 5 to 8 are lower plan views of a pellicle structure in accordance with an embodiment of the present disclosure;

FIG. 9 is a lower plan view of a pellicle structure in accordance with an embodiment of the present disclosure;

FIGS. 10A and 10B are lower plan views of a pellicle structure in accordance with an embodiment of the present disclosure;

FIG. 11 is a lower plan view of a pellicle structure having a reinforcing pattern in accordance with an embodiment of the present disclosure;

FIGS. 12A to 12D are cross-sectional views of a pellicle structure in accordance with an embodiment of the present disclosure;

FIG. 13 is a lower plan view of a pellicle structure having a reinforcing pattern in accordance with an embodiment of the present disclosure;

FIG. 14A is a lower plan view of a pellicle structure in accordance with an embodiment of the present disclosure;

FIG. 14B is a cross-sectional view taken along a line d-d′ of FIG. 14A;

FIG. 15 is a lower plan view of a pellicle structure in accordance with an embodiment of the present disclosure;

FIG. 16A is an upper plan view of a pellicle structure in accordance with an embodiment of the present disclosure, and FIG. 16B is a cross-sectional view taken along a line e-e′ in FIG. 16A;

FIG. 17 is an upper plan view of a pellicle structure in accordance with an embodiment of the present disclosure;

FIG. 18 is a flow chart illustrating a method of manufacturing a pellicle structure in accordance with an embodiment of the present disclosure; and

FIGS. 19A and 19B are cross-sectional views of process operations of a method of manufacturing a pellicle structure in accordance with an embodiment of the present disclosure.

### DETAILED DESCRIPTION

Various embodiments of the present disclosure will be described in greater detail with reference to the accompanying drawings. The drawings are schematic illustrations of various embodiments and intermediate structures. As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the technical concepts and scope of the embodiments of the present disclosure as defined in the appended claims.

Some embodiments are described herein with reference to cross-section and/or plan illustrations of the example embodiments. However, the embodiments should not be construed as limiting the disclosed inventive concepts. Although a few embodiments will be shown and described, it will be appreciated by those of ordinary skill in the art that changes may be made in these embodiments without departing from the principles and technical concept of the present disclosure.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, spatially relative terms, such as “beneath,” “below,” “bottom,” “above,” “upper,” “upper,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on upper of” the other elements or features. Thus, the term “below” may encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

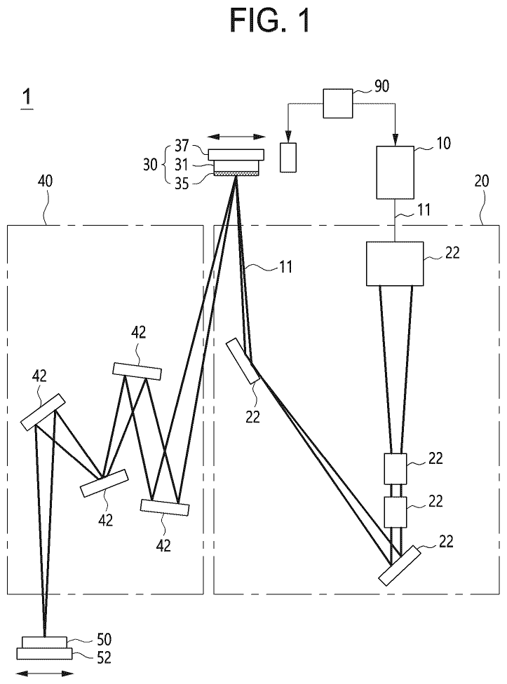

FIG. 1 is a simplified schematic block diagram of a photo lithography apparatus using a photo mask including a pellicle structure in accordance with an embodiment of the present disclosure.

Referring now to FIG. 1, a photo lithography apparatus 1 may include a light source unit 10, a condenser unit 20, a projection unit 40, and a control unit 90.

The light source unit 10 may generate light 11. The light source unit 10 may be an EUV light source generating an EUV light 11 having a wavelength of about 10 nm to about 14 nm. The light 11 generated by the light source unit 10 may be provided to the condenser unit 20.

The condenser unit 20 may focus the light 11 to the mask assembly 30. The condenser unit 20 may include at least one optical system 22. The optical system 22 may include at least a lens, a mirror, or any combination thereof.

The mask assembly 30 may include a photo mask 31 and a pellicle structure 35. The pellicle structure 35 may be disposed over a light incident surface of the photo mask 31. The mask assembly 30 may further include a stage 37 for moving the photo mask 31.

The light 11 incident on the mask assembly 30 may be reflected by the mask assembly 30 and incident on the projection unit 40. The projection unit 40 may project a pattern image of the mask assembly 30 onto a target substrate 50. The target substrate 50 may be a wafer on which an integrated circuit is to be formed. For example, the target substrate 50 may include a photoresist film reacting to the light 11. The projection unit 40 may include at least one projection optic 42. The projection optic 42 may also include a lens, a mirror, or any combination thereof. The projection optic 42 may reduce the pattern image on the mask assembly 30 to a predetermined magnification (e.g., about 4 times, about 6 times, or about 8 times) using the light 11 reflected from the mask assembly 30, and may project this onto the target substrate 50.

A reference numeral 52 may indicate a substrate stage, and

the target substrate 50 may be moved to change an exposure region (or an exposure position) of the target substrate 50.

The control unit 90 may control operations of the light source unit 10, the condenser unit 20, the mask assembly 40, the projection unit 50, and the substrate stage 52.

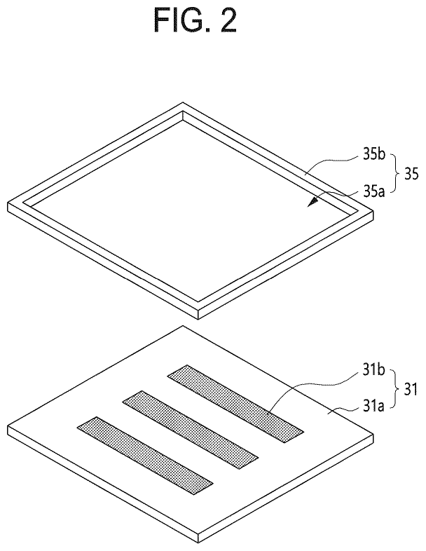

FIG. 2 is a simplified schematic exploded perspective view of a mask assembly in accordance with an embodiment of the present disclosure.

Referring to FIGS. 1 and 2, the mask assembly 30 may include a photo mask 31 and a pellicle structure 35, as described above.

The photo mask 31 may include a mask substrate 31a and a pattern image 31b formed on the mask substrate 31a. The pattern image 31b may be projected onto the target substrate 50 by light 11.

The pellicle structure 35 may be disposed over the photo mask 31 on which the pattern image 31b may be formed. The pellicle structure 35 may protect the photo mask 31 from particles and external environments. The light 11 may be transmitted to the photo mask 31 through the condenser unit 20 and the pellicle structure 35. The transmitted light 11 may be reflected from the photo mask 31. The reflected light 11 may be transmitted to the target substrate 50 through the projection unit 40. The pellicle structure 35 may include, for example, a pellicle membrane 35a and a supporter 35b.

The pellicle membrane 35a may be spaced apart from the photo mask 31 by a set distance. For example, the pellicle membrane 35a may be spaced apart from the photo mask 31 by about 1 mm to about 10 mm. The pellicle membrane 35a may be a light transmitting material. For example, the pellicle membrane 35a may have transmittance of about 80% or more, preferably about 90% or more, with respect to extreme ultraviolet (EUV) light. The pellicle membrane 35a may include various materials having high transmittance to EUV light. For example, the pellicle membrane 35a may include at least one of a single crystalline silicon material, a poly silicon material, an amorphous silicon material, SiO2, SiC, SiN, SiOCN, SiON, SiOC, a porous material, a material with dopants, a material with carbon nano tube (or carbon nano wire) and a material with metal.

The supporter 35b may support the pellicle membrane 35a. For example, the supporter 35b may be formed over the edge of the pellicle membrane 35a that faces the pattern image 31b. The supporter 35b may have a predetermined thickness to keep a gap between the pellicle membrane 35a and the photo mask 31. For example, the supporter 35b may be attached to the pellicle membrane 35a by any suitable means, including, for example, an adhesive material. The adhesive material may form, for example, an adhesive layer (not shown).

The pellicle structure 35 may be attached on the photo mask 31 by suitable means or methods.

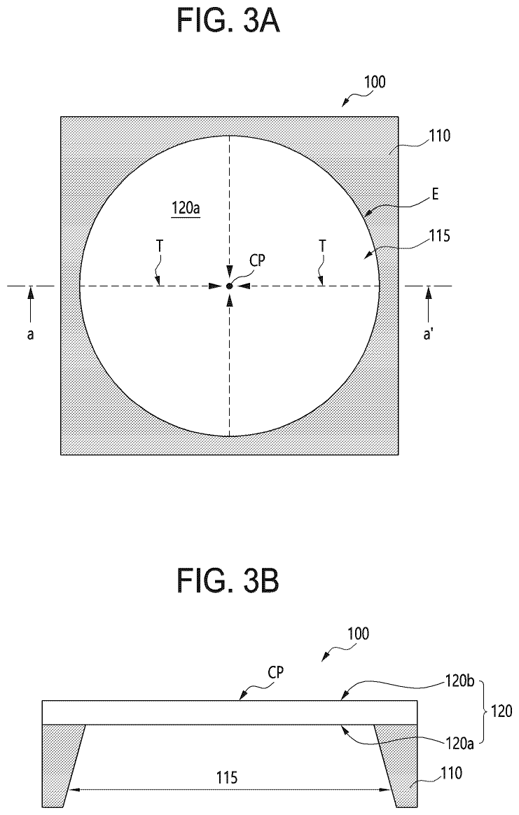

FIG. 3A is a lower plan view of the pellicle structure in accordance with an embodiment of the present disclosure and FIG. 3B is a cross-sectional view taken along a line a-a′ in FIG. 3A.

Referring to FIGS. 3A and 3B, the pellicle structure 100 may include a membrane border 110 and a pellicle membrane 120.

The membrane border 110 may support the pellicle membrane 120. The membrane border 110 may include a substrate or at least one buffer layer. The membrane border 110 may have an open region 115. In a plan view, the membrane border 110 may have a rectangular plate structure. A planar structure of the open region 115 may have at least one rounded edge. For example, at least one portion of the open region 115 may have a curvature. In some embodiments, a planar structure of the open region 115 may be circular. For example, the membrane border 110 of the embodiments may correspond to the supporting portion 35b in FIG. 2.

A membrane layer may be formed on the membrane border 110. An edge portion of the membrane layer may be attached to the membrane border 110. The membrane layer exposed by the open region 115 may become a pellicle membrane 120. Accordingly, the edge of the pellicle membrane 120 of the embodiments may have a rounded shape, that is, at least one edge of the pellicle membrane 120 may have a curvature according to a shape of the open region 115.

As will be described later, the pellicle membrane 120 may be deposited on a support layer (not shown) such as a substrate or at least one buffer layer. A predetermined portion of the support layer may be etched to form the membrane border 110 including the open region 115 exposing a lower surface of the pellicle membrane 120.

The pellicle membrane 120 may include at least one light transmitting layer. For example, the pellicle membrane 120 may include a material having transmittance of about 80% or more with respect to extreme ultraviolet rays (EUV). For example, the light transmitting layer for the pellicle membrane 120 may include at least one material layer selected from among single crystal silicon, polysilicon, amorphous silicon, SiO2, SiC, SIN, SiOCN, SION, and SiOC. Also, the light transmitting layer for the pellicle membrane 120 may include a material layer including at least one dopant among Mo, Ta, Ti, V, Co, Cu, Ni, Zr, Nb, Pd, Pt, Fe, Zn, Sn, Cr, Mn, Cd, Mg, Li, Se, Hf, Y, W, graphene (graphite), carbon nanotubes, CrN, Al, Al, Al2O3, In, B, Nb, Ru, Pr, La, Te, Rh, Eu, Al, Ga, As, Sb, and Bi. The light transmitting layer may include a metal-containing material layer including at least one of a metal silicide material, MoS2, MoSe2, WS2, MoSe2, MoTe2, and WTe2. The light transmitting layer for the pellicle membrane 120 may include a porous material layer. The porous material layer may include a plurality of pores (not shown) having a honeycomb shape or a lattice shape. For reference, various examples of the pellicle membrane 120 are disclosed in detail in Korean Patent Publication No. 10-2023-0112911 which is incorporated herein by reference in its entirety.

The pellicle membrane 120 may have a thickness of about 1 nm to about 200 nm. The pellicle membrane 120 may include a lower surface 120a and an upper surface 120b. In some embodiments, an edge portion of the membrane layer, that is, an outer portion of the lower surface 120a of the pellicle membrane 120 may be attached to the membrane border 110. The lower surface 120a and the upper surface 120b of the pellicle membrane 120, which are opened by the open region 115, may be a part of the membrane layer.

Since at least one edge of the open region 115 has a curvature, for example, the planar structure of the open region 115 may be a substantially circular shape, a center point CP of the pellicle membrane 120 and entire edges E of the open region 115 may be maintained at the same distance. Since the edge portion of the membrane layer may be attached to the membrane border 110, and the entire edges E of the open region 115 are spaced apart by the same distance from the center point CP, the same tension T may be provided from the edge E to the center point CP.

In this case, because the membrane border 110 may have a sufficiently small size corresponding to the size of the photo mask 31, not only the center point CP of the pellicle membrane 120 but also the entire region of the pellicle membrane 120 exposed by the open region 115 may maintain a tension equilibrium state, for example, the tension equilibrium state refer to a condition where the pellicle membrane has a balanced distribution of forces across its surface, resulting in minimal deformation or wrinkles. Therefore, wrinkles and other shape deformation due to tension unbalance of the pellicle membrane 120 may be prevented. As a result, the pellicle structure 100 may protect the photo mask without pattern errors.

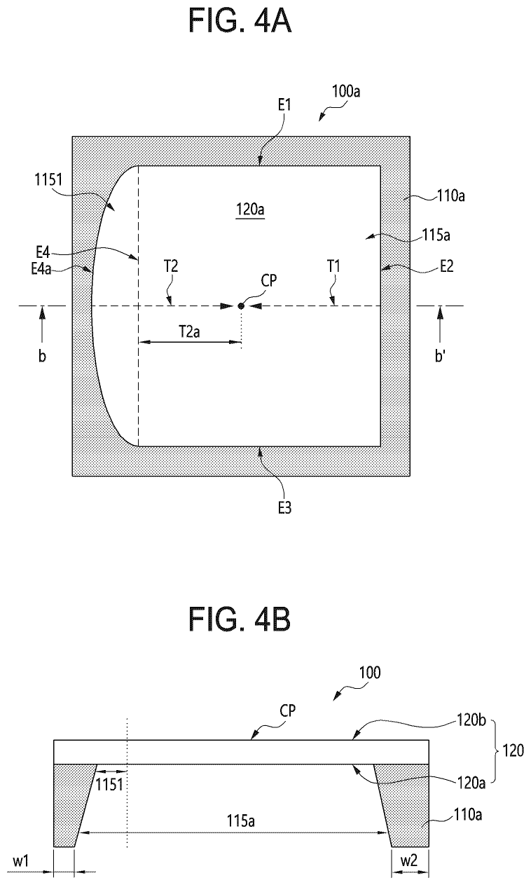

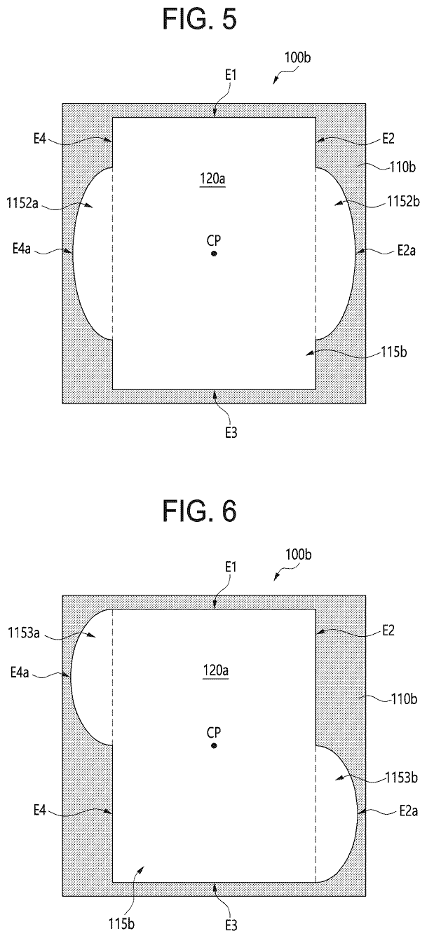

FIG. 4A is a lower plan view of a pellicle structure in accordance with an embodiment of the present disclosure, and FIG. 4B is a cross-sectional view taken along a line b-b′ of FIG. 4A. FIGS. 5 to 8 are lower plan views of a pellicle structure in accordance with embodiments of the present disclosure.

Referring to FIGS. 4A and 4B, a pellicle structure 100a may include a membrane border 110a surrounding an open region 115a. The membrane border 110a defines the open region 115a. The pellicle structure 100a may further include a pellicle membrane 120a. The pellicle membrane 120a extends over the open region 115a and covers the entire region 115a. The pellicle membrane 120a is in contact with the membrane border 110a. The pellicle membrane 120a may extend partially or wholly over the membrane border 110a. The membrane border 110a may support the pellicle membrane 120a.

The membrane border 110a may have a shape and a size corresponding to the photo mask 31 of FIG. 2, for example, a rectangular plate shape, and the open region 115a may be positioned inside the rectangular plate.

A membrane layer for the pellicle membrane 120 may be formed over the membrane border 110a. Edges of the lower surface of the membrane layer may be attached to the membrane border 110a. A lower surface of the membrane layer, excluding the edges of the membrane layer may be a lower surface 120a of the pellicle membrane 120 exposed by the open region 115a.

In some embodiments, a planar structure of the open region 115a may have a polygonal, for example, a substantially rectangular structure including edges E1, E2, E3 and E4. For example, one of the edges E1 to E4 may include a curvature portion 1151. In the embodiment of FIG. 4A, edge E4 includes a curvature portion 1151. For example, the curvature portion 1151 of the embodiments may be asymmetrically disposed in order to compensate for the non-uniform tension. That is, by forming the curvature portion 1151 at an edge of a portion where the wrinkle occurs, the loosened tension may be compensated for to remove the wrinkle.

For example, when wrinkles may be generated at a portion corresponding to the edge E4 of the pellicle membrane 120a, the curvature portion 1151 may be formed at the edge E4 of the open region 115a to change the position of the edge E4a of the open region 115a. For reference, in FIG. 4A, E4a may refer to a rounded edge of the curvature portion 1151, and E4 may be a straight virtual edge before the curvature portion 1151 is formed.

The edge E4a of the curvature portion 1151 may extend toward the outside of the membrane border 110a in a rounded shape. Accordingly, a distance from the center point CP to the rounded edge E4a may be relatively increased with respect to the distance from the center point CP to the virtual edge E4. Thus, a relatively large tension T2 may be provided at a portion where the curvature portion 1151 is formed. Here, the center point CP may be a center point of an open region having a rectangular structure in which no curvature portion is formed.

Accordingly, the tension unbalance may be resolved by the open region 115a having the curvature portion 1151, thereby preventing an occurrence of wrinkles in a specific portion.

Further, the membrane border 110a may have various line widths due to the shape of the open region 115a. In particular, the line width w1 of the membrane border 110a in which the curvature portion 1151 is located may be narrower than the line width w2 of the membrane border 110a in which the curvature portion 1151 is not provided.

As described above, a position and a shape of the curvature portion 1511 may be variously modified in consideration of a wrinkle occurrence position and a wrinkle shape of the pellicle membrane 120.

In some embodiments, referring to FIG. 5, the membrane border 110b of the pellicle structure 100b may include an open region 115b including a plurality of curvature portions 1152a and 1152b.

The open region 115b may have a substantially rectangular structure with curvature portions 1152a and 1152b formed at two opposite edges E2 and E4 facing each other. The curvature portions 1152a and 1152b may be symmetrically formed at portions of the edges E2 and E4. The curvature portions 1152a and 1152b may be formed with respect to the entire edges E2 and E4 (see FIG. 4A) or with respect to a part of the edges E2 and E4 (See FIG. 5). Further, the curvature portions 1152a and 1152b may be formed to face each other and may have the same size.

As an example, as shown in FIG. 6, curvature portions 1153a and 1153b are disposed on portions of two sides E2 and E4 facing each other. The curvature portions 1153a and 1153b may be disposed to be diagonally symmetrical to each other.

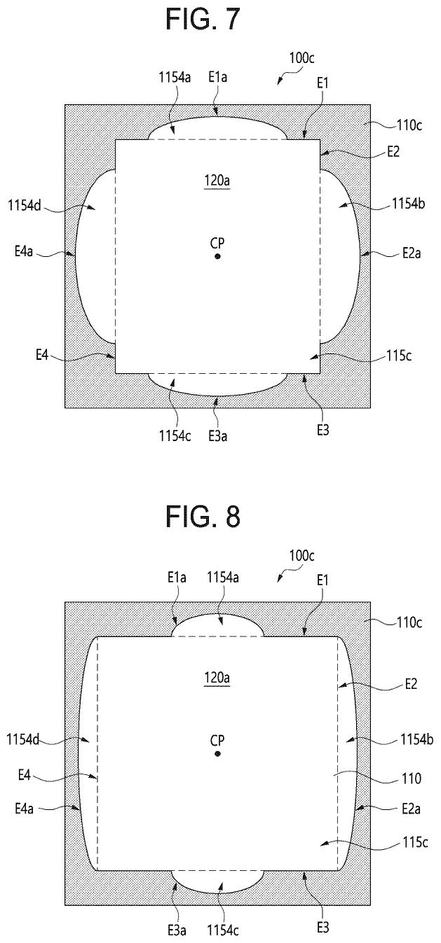

In some embodiments, as shown in FIGS. 7 and 8, the membrane border 110c may include curvature portions 1154a, 1154b, 1154c, and 1154d formed on each of the four edges E1, E2, E3, and E4 of the open region 115c. The curvature portions 1154a, 1154b, 1154c, and 1154d may be symmetrically disposed at each of the edges E1, E2, E3, and E4 and may have the same size. In another embodiment, as shown in FIG. 8, the curvature portions 1154a, 1154b, 1154c, and 1154d may form two pairs of symmetrical curvature portions, i.e., a first pair including the curvature portions 1154a and 1154c, and a second pair including curvature portions 1154b and 1154d. The first and second pairs may have different sizes. For example, as illustrated in the embodiment of FIG. 8, the curvature portion 1154a may be smaller than the curvature portion 1154b.

In FIGS. 5 to 8, the edges E1, E2, E3, and E4 may indicate a straight edge, and each of the edges E1a, E2a, E3a, and E4a may indicate a rounded edge provided by the curvature portions 1151, 1152a, 1152b, 1153a, 1153b, 1154a, 1154b, 1154c, and 1154d.

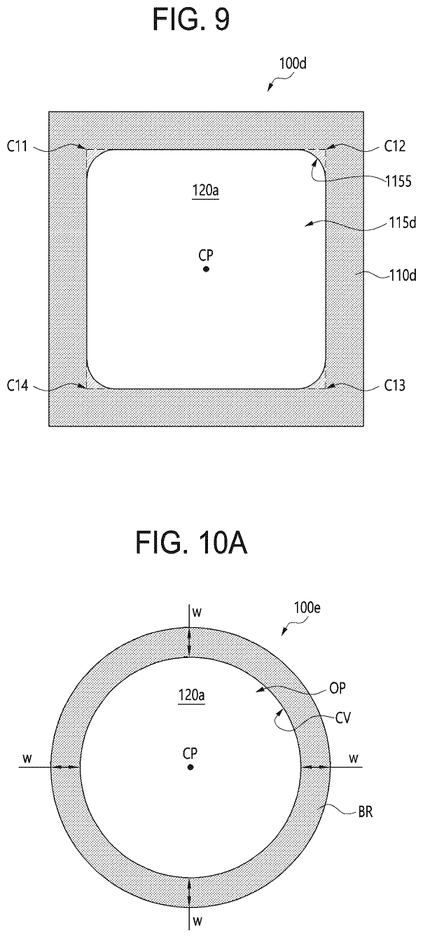

FIG. 9 is a lower plan view of a pellicle structure according to an embodiment of the present disclosure.

Referring to FIG. 9, the membrane border 110d of the pellicle structure 100d may include an open region 115d.

For example, the membrane border 110d may have a rectangular plate, and the open region 115d may be formed within the rectangular plate and may have a substantially rectangular structure in a plan view. In this case, at least one of the four corners C11, C12, C13, and C14 of the open region 115d may be rounded to serve as a curvature portion.

Since the corner portions C11, C12, C13, and C14 may be the farthest point from the center point CP, the corner portions C11, C12, C13, and C14 are the points where the two edges meet, and the corner portions C11, C12, C13 and C14 are vulnerable to stress, an occurring frequency of the tension unbalance increases at the corner portions C11, C12, C13 and C14. The chamfered curvature portion 1155 may be provided on at least one of the corner portions C11, C12, C13, and C14 of the open region 115d, thereby mitigating the tension unbalance and the stress.

In some embodiments, the membrane borders 110a to 110d illustrate a planar structure of the rectangular plate in consideration of the shape of the photo mask, but the embodiments are not limited thereto.

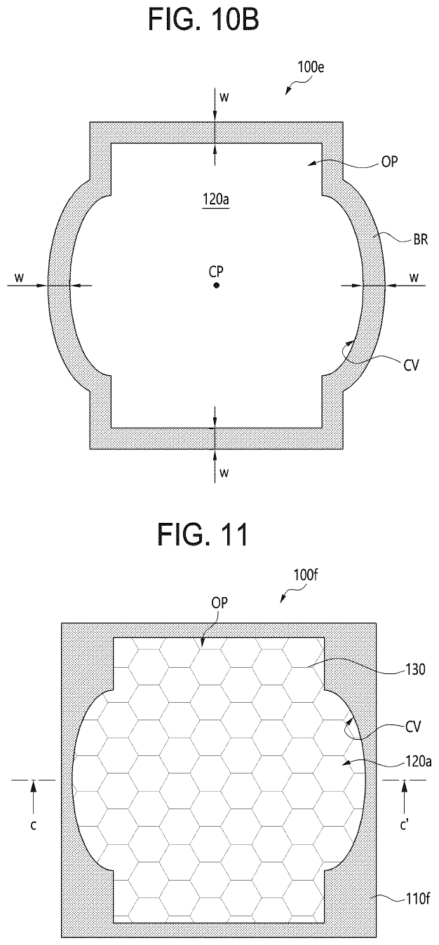

FIGS. 10A and 10B are lower plan views of a pellicle structure in accordance with an embodiment of the present disclosure.

Referring to FIGS. 10A and 10B, the pellicle structure 100e may include a membrane border BR having an open region OP and a pellicle membrane 120a positioned on the membrane border BR.

The membrane border BR may include various types of open regions OP having a curvature portion CV. The pellicle membrane 120a may be exposed by the open region OP.

The membrane border BR of some embodiments may have a ring structure having a uniform line width w. For example, as illustrated in FIG. 10A, when a planar structure of the open region OP has a circular shape, the membrane border BR may have a circular ring structure.

In addition, as illustrated in FIG. 10B, when a planar structure of the open region OP has a polygonal structure, the membrane border BR may have a polygonal ring structure. Since the membrane border BR may be formed to have a uniform line width w, edges of a membrane layer for the pellicle membrane 120 may be attached to the membrane border BR with a uniform fixing force. It is noted that the embodiments are not limited to the polygonal planar structure of the open regions OP in FIGS. 10A and 10B, and the planar structure of the open regions OP may be modified into various forms.

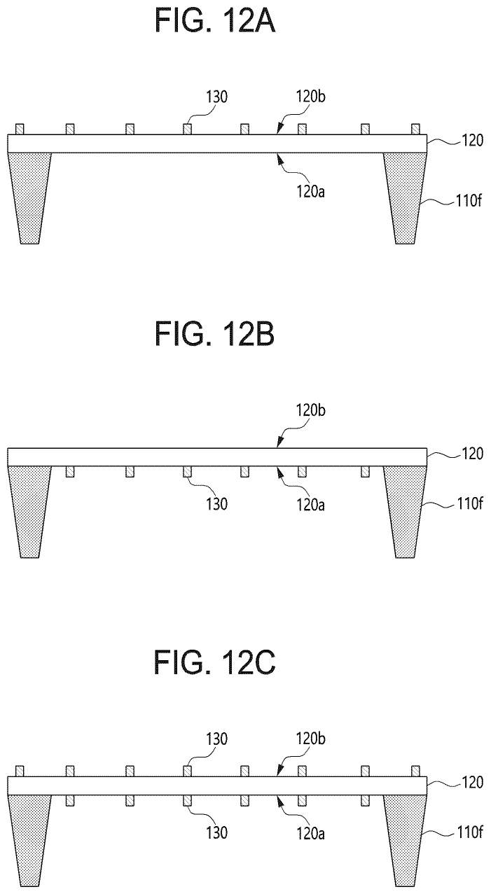

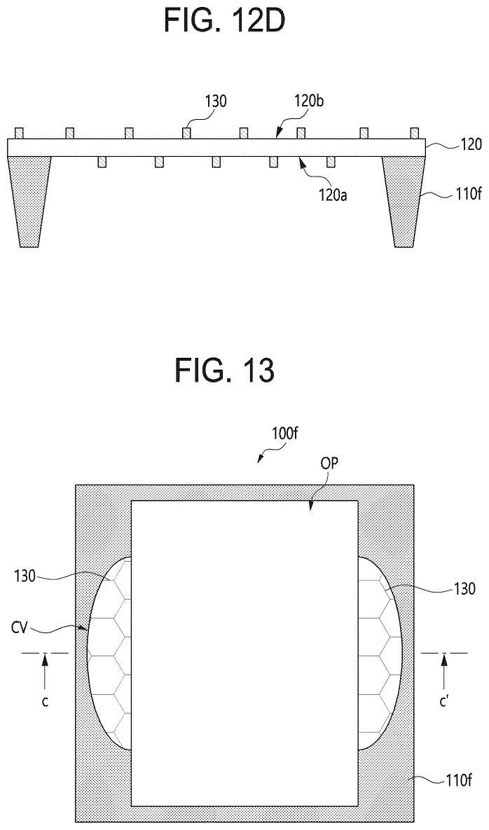

FIG. 11 is a lower plan view of a pellicle structure having a reinforcement pattern in accordance with an embodiment of the present disclosure. FIGS. 12A to 12D are cross-sectional views of a pellicle structure in accordance with an embodiment of the present disclosure. For reference, FIGS. 12A to 12D are cross-sectional views taken along a line c-c′ of FIG. 11. FIG. 13 is a lower plan view of a pellicle structure having a reinforcement pattern in accordance with an embodiment of the present disclosure.

Referring to FIGS. 11 and 12A to 12D, the pellicle structure 100f may include a membrane border 110f, a pellicle membrane 120a and a plurality of reinforcing patterns 130.

The membrane border 110f may include an open region OP having at least one curvature portion CV. In FIG. 11, the membrane border 110f may include the open region OP having two curvature portions CV, however, any one of the above-described embodiments may be applied to the shape and size of the curvature portion CV and the open region OP of FIG. 11.

The pellicle membrane 120 may be supported by the membrane border 110f. Further, the pellicle membrane 120 may be exposed by the open region OP including the curvature portion CV.

The reinforcement patterns 130 may be formed on the pellicle membrane 120. The reinforcement patterns 130 may be disposed on the upper surface 120b of the pellicle membrane 120 with a predetermined distance, as shown in FIG. 12A. Alternately, the reinforcement patterns 130 may be disposed on the lower surface 120a of the pellicle membrane 120 with a predetermined distance therebetween, as shown in FIG. 12B.

In addition, as shown in FIG. 12C, the reinforcement patterns 130 may be disposed to correspond to each other on the upper surface 120b and the lower surface 120a of the pellicle membrane 120.

Further, as shown in FIG. 12D, the reinforcement patterns 130 disposed on the upper surface 120b of the pellicle membrane 120 and the reinforcement patterns 130 placed on the lower surface 120a of the pellicle membrane 120 may be disposed so as not to overlap each other.

In some embodiments, the reinforcement patterns 130 may be arranged in the form of a mesh, a honeycomb, and a line in a plan view.

The reinforcing patterns 130 may prevent a sagging phenomenon due to a load on the pellicle membrane 120. Also, the reinforcing patterns 130 may include a light transmitting material, for example, a material that does not affect the transmittance of the pellicle membrane 120.

Further, the reinforcement patterns 130 may be disposed on at least one of the lower surface 120a and the upper surface 120b of the pellicle membrane 120 corresponding to the curvature portion CV, as shown in FIG. 13. For example, the reinforcement patterns 130 positioned on each of the lower surface 120a and the upper surface 120b of the pellicle membrane 120 corresponding to the curvature portion CV may also be disposed to overlap each other or not to overlap each other, as shown in FIGS. 12C and 12D.

The reinforcing pattern 130 may improve the flatness of the pellicle membrane 120 together with the curvature portion CV.

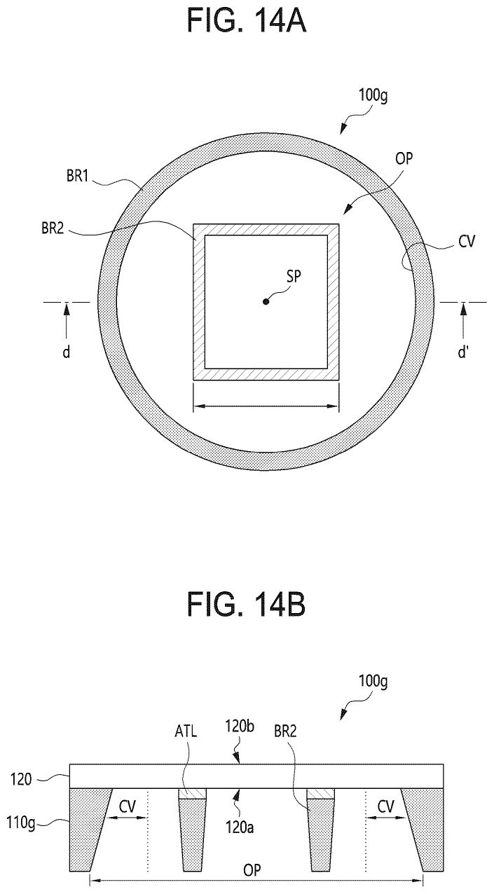

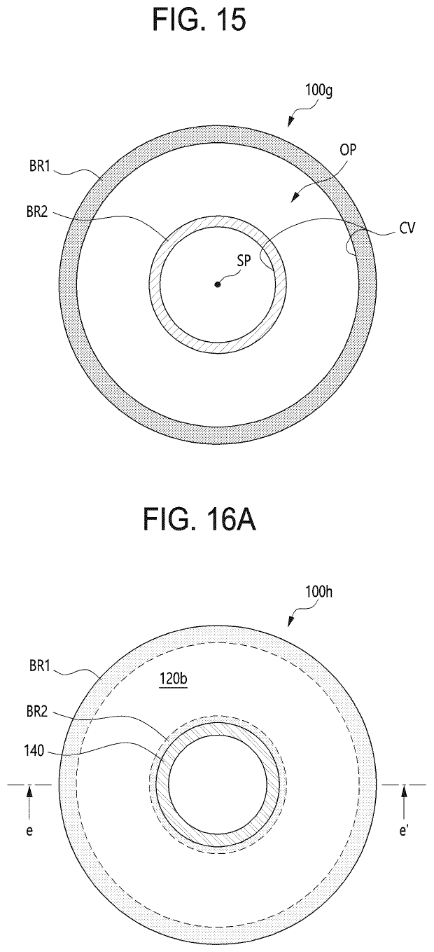

FIG. 14A is an upper plan view of a pellicle structure in accordance with an embodiment of the present disclosure. FIG. 14B is a cross-sectional view taken along a line d-d′ of FIG. 14A. FIG. 15 is a lower plan view of a pellicle structure in accordance with an embodiment of the present disclosure.

Referring to FIGS. 14A and 14B, a pellicle structure 100g may include an outer border BR1, a pellicle membrane 120, and an inner border BR2.

A pellicle membrane 120 may be disposed over an upper portion of the outer border BR1. The outer border BR1 may include an open region OP having at least one curvature portion CV. An edge of the pellicle membrane 120 may have at least one curvature portion CV by the open region. The lower surface 120a and the upper surface 120b of the pellicle membrane 120 may be exposed by the open region OP. At least one of the above-described embodiments may be applied to the shape and size of the curvature portion CV and the open region OP.

A membrane layer for forming the pellicle membrane 120 may be attached to the external border BR1. Also, since the edge of the pellicle membrane 120 is rounded by the curvature portion CV, a shape deformation such as wrinkles may be prevented. As described above, the curvature portion CV may induce the tension balance at a specific point SP of the pellicle membrane 120. The specific point SP may include a center point of the pellicle membrane 120 exposed by the open region OP, but the embodiments are not limited thereto. For example, the specific point SP for maintaining a tension balance of the pellicle membrane 120 may vary according to a position and shape of the curvature portion CV.

The inner border BR2 may be formed on the lower surface 120a of the pellicle membrane 120. The inner border BR2 may be bonded to the lower surface 120a of the pellicle membrane 120 through an adhesive layer ATL. In an embodiment, the inner border BR2 may be formed of the same material as or different from that of the outer border BR1. For example, the inner border BR2 may include aluminum (Al), anodized aluminum, stainless steel (SUS), similar diamond carbon (DLC) treated aluminum, DLC treated SUS, silicon, or a combination thereof, but the embodiments are not limited thereto.

For example, a thickness of the inner border BR2 may be equal to a thickness of the outer border BR1, but the embodiments are not limited thereto. Alternately, the thickness of the inner border BR2 may be thinner than the thickness of the outer border BR1.

The inner border BR2 may be positioned inside the open region OP such that the specific point SP and an adjacent region of the specific point SP are exposed. For example, a membrane portion positioned inside the inner border BR2 may be a region where the highest tension is applied to the pellicle membrane 120.

For example, the inner border BR2 may be formed in a rectangular frame shape as illustrated in FIG. 14A. Further, the inner border BR2 may be formed to have a curvature portion CV as shown in FIG. 15. The line width of the inner border BR2 may be equal to or different from the line width of a pellicle frame that may be subsequently formed.

Further, the inner border BR2 may stably support the pellicle membrane 120 within the open region OP and additionally compensate for preventing a tension unbalance of the specific point SP and the adjacent region of the specific point SP.

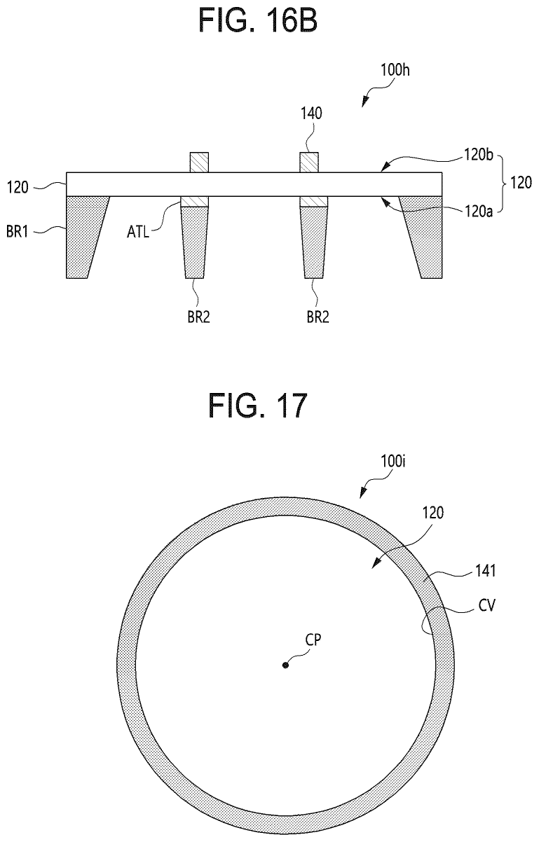

FIG. 16A is an upper plan view of a pellicle structure in accordance with an embodiment of the present disclosure. FIG. 16B is a cross-sectional view taken along a line e-e′ in FIG. 16A.

Referring to FIGS. 16A and 16B, the pellicle structure 100h may further include a pellicle frame 140 formed on the upper surface 120b of the pellicle membrane 120 having the outer border BR1 and the inner border BR2. The pellicle frame 140 may be disposed to expose a region having the highest tension in the pellicle membrane 120. For example, the pellicle frame 140 may be disposed over the upper surface 120b of the pellicle membrane 120 to open the specific point SP and the adjacent region of the specific point SP. For example, the pellicle frame 140 may be formed to overlap the inner border BR2.

In some embodiments, the pellicle frame 140 and the inner border BR2 may be formed in the same shape as shown in FIG. 16A, but the embodiments are not limited thereto. For example, the inner border BR2 may be formed in the rectangular frame shape as shown in FIG. 14A, and the pellicle frame 140 may be formed in the ring shape as shown in FIG. 16A. For example, the inner border BR2 may be formed in the ring shape as shown in FIG. 16A and the pellicle frame 140 may also be formed in the rectangular frame shape as the inner border BR2 of FIG. 14A.

The pellicle frame 140 may be variously changed in consideration of a size and shape of the photo mask, for example.

FIG. 17 is an upper plan view of a pellicle structure in accordance with an embodiment of the present disclosure.

Referring to FIG. 17, a pellicle structure 100i may include a pellicle frame 141 having a curvature portion CV and a pellicle membrane 120.

The pellicle frame 141 may include a curvature portion CV. Edges of the pellicle membrane 120 may be attached to one of an upper surface of the pellicle frame 141 and a lower surface of the pellicle frame 141.

In some embodiments, as the pellicle frame 141 is formed to have the curvature portion CV, a uniform tension is applied to all edges of the pellicle membrane 120 from the center portion CP of the pellicle membrane 120, thereby preventing the occurrence of wrinkles at the edge portion of the pellicle membrane 120. For example, the pellicle frame 141 may correspond to the support portion 35b of FIG. 2.

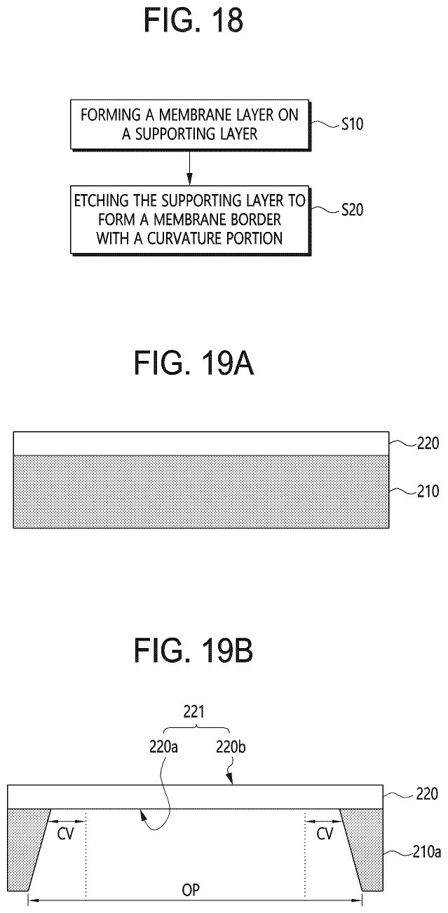

FIG. 18 is a flow chart illustrating a method of manufacturing a pellicle structure in accordance with embodiments of the present disclosure. FIGS. 19A and 19B are cross-sectional views of each operation for illustrating a method of manufacturing a pellicle structure in accordance with an embodiment of the present disclosure.

Referring to FIGS. 18 and 19A, a membrane layer 220 may be formed on a supporting layer 210 (S10).

For example, the supporting layer 210 may include a semiconductor wafer, a silicon-on-insulator (SOI) substrate, a metal-containing buffer layer, a polymer, or a resin layer. In some embodiments, the support layer 210 may have a size corresponding to a wafer. However, the embodiments are not limited thereto and may have various sizes.

For example, the membrane layer 220 may be formed by a chemical vapor deposition (CVD), but the embodiments are not limited thereto. The lower surface of the membrane layer 220 may be attached to the entire surface of the supporting layer 210.

Referring to FIGS. 18 and 19B, the supporting layer 220 may be etched to form a membrane border 210a with a curvature portion CV (S20).

For example, the supporting layer 210 may be etched such than the membrane border 210a remains at an edge of the membrane layer 220. The supporting layer 210 may be etched using at least one of a dry etching and a wet etching.

In some embodiments, the membrane layer corresponding to an open region OP exposed by the membrane border 210a becomes a pellicle membrane.

In some embodiments, an inner edge of the membrane border 210a may be rounded by the curvature CV. Thus, the pellicle membrane may include a uniform tension.

In some embodiments, as shown in FIGS. 14A to 16B, the inner border BR2 may be further formed on a lower surface 220a of the pellicle membrane 221 inside the membrane border 210a.

As shown in FIGS. 16A and 16B, after the inner border BR2 is formed, the pellicle frame 140 may be further formed on the upper surface 220b of the pellicle membrane 221.

According to some embodiments, the membrane border may include an open region having a curvature portion. A tension unbalance of the membrane may be compensated for by the curvature portion of the pellicle membrane, thereby preventing a pattern error such as wrinkles occurring at edges or corners of the pellicle membrane.

The above described embodiments of the present disclosure are intended to illustrate and not to limit the embodiments. Various alternatives and equivalents are possible. The invention is not limited by the embodiments described herein. Nor is the invention limited to any specific type of semiconductor device. Other additions, subtractions, or modifications which are apparent in view of the present disclosure, are intended to fall within the scope of the appended claims. Furthermore, the embodiments may be combined to form additional embodiments.

What is claimed is:

1. A pellicle structure comprising:
a membrane border defining an open region;
a pellicle membrane in contact with the membrane border and extending over the open region.

2. The pellicle structure of claim 1, wherein a planar structure of the open region is circular or polygonal with at least one edge being wholly or partially extended with a curvature portion, and wherein the pellicle membrane is made of a material having a transmittance of about 80% or more with respect to extreme ultraviolet (EUV) light.

3. The pellicle structure of claim 1, wherein a planar structure of the open region has a polygonal shape, and the curvature portion is provided to at least one of edges and corners of the open region.

4. The pellicle structure of claim 3, wherein the open region includes a plurality of curvature portions, and
wherein the plurality of curvature portions are asymmetrically disposed at the edges of the open region and/or the corners of the open region.

5. The pellicle structure of claim 1, wherein the open region includes a plurality of curvature portions, and
wherein the plurality of curvature portions are disposed symmetrically with each other at the edges of the open region and/or the corners of the open region.

6. The pellicle structure of claim 1, wherein the open region includes a plurality of curvature portions, and
wherein sizes of the curvature portions are equal.

7. The pellicle structure of claim 1, wherein the open region includes a plurality of different shapes and/or sizes of curvature portions.

8. The pellicle structure of claim 1, wherein a planar structure of the membrane border has a rectangular plate shape, and the open region is located inside the rectangular plate.

9. The pellicle structure of claim 1, wherein the membrane border is configured to have a uniform line width along an edge of the open region.

10. The pellicle structure of claim 1, further comprising a reinforcing pattern disposed on at least one of an upper surface and a lower surface of the pellicle membrane.

11. The pellicle structure of claim 10, wherein the reinforcing pattern is selectively disposed on the curvature portion of the pellicle membrane.

12. The pellicle structure of claim 1, further comprising an inner border disposed on a lower surface of the pellicle membrane positioned inside the membrane border.

13. The pellicle structure of claim 12, wherein the inner border is formed to expose a specific point and an adjacent region of the specific point, and
wherein the specific point and the adjacent region of the specific point are an area of highest tension in the pellicle membrane.

14. The pellicle structure of claim 13, further comprising a pellicle frame formed on an upper surface of the pellicle membrane,
wherein at least one portion of the pellicle frame is overlapped with the inner border.

15. The pellicle structure of claim 14, wherein an edge of the pellicle frame includes a curvature portion.

16. A pellicle structure comprising:
a membrane;
an outer border disposed on edges of a lower surface of the membrane, the outer border including a ring shape; and
an inner border disposed inside the outer border and on the lower surface of the membrane,
wherein at least one of the edge of the membrane exposed by the outer border and the edge of the membrane exposed by the inner border has a curvature portion.

17. The pellicle structure of claim 16, wherein the inner border is configured in a ring shape to expose a center point of the membrane and an adjacent region of the center point.

18. The pellicle structure of claim 16, further comprising a pellicle frame disposed on an upper surface of the membrane,
wherein at least one portion of the pellicle frame is overlapped with the inner border.

19. A pellicle structure comprising:
a pellicle membrane; and
a pellicle frame including an open region, the pellicle frame configured to expose the pellicle membrane through the open region,
wherein at least one part of the open region has a curvature portion.

20. The pellicle structure of claim 19, wherein the pellicle frame has a size corresponding to a size of a photo mask.

21. A pellicle structure comprising:
a membrane border defining an open region; and
a pellicle membrane extending over the open region and contacting membrane border,
wherein the open region has a shape of:
wholly circular or part circular, or
polygonal with at least one edge of the polygonal shape being wholly or partially extended with a curvature portion, and
wherein the pellicle membrane is made of a material having a transmittance of about 80% or more with respect to extreme ultraviolet (EUV) light.
